(19) United States
(12) Patent Application Publication
(10) Pub. No.: US 2015/0015793 A1
(43) Pub. Date: Jan. 15, 2015

(54) DISPLAY DEVICE AND TELEVISION RECEIVER

(71) Applicant: Sharp Kabushiki Kaisha, Osaka-shi, Osaka (JP)

(72) Inventor: Yoshihisa Noguchi, Osaka-shi (JP)

(73) Assignee: Sharp Kabushiki Kaisha, Osaka-shi, Osaka (JP)

(21) Appl. No.: 14/368,892

(22) PCT Filed: Dec. 21, 2012
(86) PCT No.: PCT/JP2012/083184

§ 371 Date: Jun. 26, 2014

(30) Foreign Application Priority Data
Dec. 27, 2011 (JP) 2011-286456
May 24, 2012 (JP) 2012-119012

(51) Int. Cl. H05K 5/00; H04N 5/655; H04N 5/645

(52) U.S. Cl. CPC H05K 5/0004; H05K 5/0017; H04N 5/645; H04N 5/655
USPC 348/725; 361/724

(57) ABSTRACT

Provided is a display device and a television receiver each has a frame at a circumferential part of a display panel, the frame having a smaller level difference and a gap at a coupling section of frame members.

In a display device comprising a display panel 1 that displays an image and a rectangular frame-shaped cabinet 3 that covers the display panel 1, the cabinet 3 is formed by bringing end parts of members constituting sides of a rectangular frame into contact with each other so as to couple the members with each other. A contacting end part of each of the members is provided with a regulating part that engages with a corresponding regulating part and regulates a relative movement of each of the members.

### CROSS-REFERENCE TO RELATED APPLICATIONS

This application is the national phase under 35 U.S.C. §371 of PCT International Application No. PCT/JP2012/083184 which has an International filing date of Dec. 21, 2012 and designated the United States of America.

### TECHNICAL FIELD

The present invention relates to a display device that displays an image and a television receiver having the display device.

### BACKGROUND ART

Conventionally, aluminum may be used for a cabinet in a television receiver in order to provide a good appearance and a high class feeling. Such a cabinet using aluminum is constituted by four frame members. An extrusion processing is adopted for forming each of the frame members.

In this configuration, as the cabinet is formed by combining frame members, a displacement, a gap or the like is generated between the frame members due to a machining error.

Japanese Patent Application Laid-Open No. 2002-190997 describes a cabinet for a television receiver, which is configured by coupling four frame members in a rectangular shape, which are formed by extrusion processing of aluminum. An end part of each of the frame members has a right angle with respect to the longitudinal direction of the frame member. When two frame members adjacent to each other are coupled, an end face of one of the frame members is brought into contact with an inner face of the other frame member, and a corner bracket (an L-shaped coupling metal fitting having a triangle-shaped member on its side face) is attached to the contacting portion, thereby fixing the frame members.

Japanese Patent Application Laid-Open No. 2008-136068 describes a television receiver having a front cabinet and a rear cabinet in which the rear cabinet is formed by coupling four frame members in a rectangular shape. An end face of each of the frame members is inclined at approximately 45 degrees with respect to the longitudinal direction of the frame member. At each of the frame members, a recessed groove is formed which extends from one end to the other end of the frame member and along the longitudinal direction of the frame member. When two frame members are coupled, a substantially L-shaped coupling metal fitting is inserted into recessed grooves of the adjacent frame members, thereby bringing the end faces of the two frame members into contact with each other and screwing them together.

### BRIEF SUMMARY OF THE INVENTION

### Problems to be Solved

However, in the above-mentioned cabinet, the contacting face of two frame members adjacent to each other is a flat surface and also the positions of the frame members are regulated by only a coupling metal fitting. Therefore, a displacement or a gap is easily caused at the coupling part of the two frame members.

Causing a displacement or a gap gives a bad appearance to the cabinet and lowers the commodity value. Therefore, assembling a cabinet requires time and effort.

The present invention is made in view of the above circumstances. An object of the present invention is to provide a display device and a television receiver which have a cabinet in which a displacement or a gap in a coupling part of frame members is reduced.

### Means to Solving the Problem

A display device according to the present invention is characterized by comprising a display panel that displays an image; and a rectangular frame-shaped cabinet that covers a circumferential part of the display panel, wherein the cabinet is formed by bringing end parts of members constituting respective sides of a rectangular frame into contact with each other so as to couple the members with each other, an end part of each of the members includes a plate-like part which has a thickened part narrower than a width of the plate-like part, and the thickened part is provided with a regulating part that engages with a corresponding regulating part and regulates a relative movement of each of the members, the regulating part comprises: a plurality of projections provided at one of the members, which protrude from the end part in a longitudinal direction and have different projecting lengths or shapes of tips; and a plurality of openings provided at another one of the members, to which each of the plurality of projections can be inserted.

In the present invention, by engaging a plurality of projections provided at one of the members with a plurality of projection receiving parts provided at another one of the members, a relative movement of each of the members is regulated. Thus, it is possible to reduce a displacement, a gap in a coupling part between the members constituting the cabinet.

The display device according to the present invention is characterized in that said another member comprises a second projection protruding from the end part in a longitudinal direction, and said one member further comprises a second projection receiving part that engages with the second projection.

In the present invention, as said another member comprises a second projection, and said one member comprises a second projection receiving part which engages with the second projection, it is possible to surely reduce a displacement, a gap in a coupling part of the members constituting the cabinet.

A display device according to the present application in characterized by comprising: a display panel that displays an image; and a rectangular frame-shaped cabinet that covers a circumferential part of the display panel, wherein the cabinet is formed by bringing end parts of members constituting respective sides of a rectangular frame into contact with each other so as to couple the members with each other, and an end part of each of the members is provided with a regulating part that engages with a corresponding regulating part and regulates a relative movement of each of the members, the regulating part comprises: a projection provided at one of the members, which protrudes from the end part in a longitudinal direction and has a bifurcated part at a tip of the projection; and a hole provided at another one of the members, to which the projection can be inserted; the projection penetrates the hole; and a separating distance between one end and another end of the bifurcated part, which protrude from the hole, is partially greater than a dimension of the hole.

In the present invention, a projection penetrates a hole and a separating distance between one end and another end of the bifurcated part, which projects from the hole, is partially greater than a dimension of the hole. Accordingly, it is possible to fix the projection to the projection receiving part without using a part for fixing, such as a coupling metal fitting or a screw. Therefore, it is possible to reduce the number of components and assembly man-hours.

A television receiver according to the present invention is characterized by comprising the above-described display device; and a receiving part that receives a television broadcast, wherein an image is displayed on the display device based on the television broadcast received at the receiving part.

According to the present invention, by engaging a plurality of projections provided at one of the members with a plurality of projection receiving parts provided at another one of the members, a relative movement of each of the members is regulated. Thus, it is possible to reduce a displacement, a gap in a coupling part of the members constituting a cabinet.

### Effect of the Invention

According to the present invention, by engaging a plurality of projections provided at one of the members with a plurality of projection receiving parts provided at another one of the members, a relative movement of each of the members is regulated. Thus, it is possible to reduce a displacement, a gap in a coupling part of the members constituting a cabinet.

### BRIEF DESCRIPTION OF THE DRAWINGS

FIG. 1 is an appearance perspective view illustrating a configuration example of a television receiver according to Embodiment b 1;

FIG. 2 is simplified cross sectional view illustrating a cross section taken from II-II in FIG. 1, in which a main part is enlarged;

FIG. 3A is a perspective view illustrating an example of the shape of the end part of a frame member constituting a front cabinet;

FIG. 3B is a perspective view illustrating an example of the shape of the end part of a frame member constituting a front cabinet;

FIG. 4A is a perspective view illustrating an example of the shape of the end part of a frame member constituting a front cabinet;

FIG. 4B is a perspective view illustrating an example of the shape of the end part of a frame member constituting a front cabinet;

FIG. 5 is a perspective view illustrating a coupled state of two frame members;

FIG. 6 is a perspective view illustrating a coupled state of two frame members;

FIG. 7A is a perspective view illustrating an example of the shapes of the end parts of frame members constituting a front cabinet according to Embodiment 2;

FIG. 7B is a perspective view illustrating an example of the shapes of the end parts of frame members constituting a front cabinet according to Embodiment 2;

FIG. 8A is a perspective view illustrating an example of the shapes of the end parts of frame members constituting a front cabinet according to Embodiment 3;

FIG. 8B is a perspective view illustrating an example of the shapes of the end parts of frame members constituting a front cabinet according to Embodiment 3;

FIG. 9A is a perspective view illustrating an example of the shape of the end part of a frame member constituting a front cabinet according to Embodiment 4;

FIG. 9B is a perspective view illustrating an example of the shape of the end part of a frame member constituting a front cabinet according to Embodiment 4;

FIG. 10A is a perspective view illustrating an example of the shape of the end part of a frame member constituting a front cabinet according to Embodiment 4;

FIG. 10B is a perspective view illustrating an example of the shape of the end part of a frame member constituting a front cabinet according to Embodiment 4;

FIG. 11A is a perspective view illustrating a coupling state of two frame members; and

FIG. 11B is a perspective view illustrating a coupling state of two frame members.

### BEST MODE FOR CARRYING OUT THE INVENTION

A display device according to the embodiments of the present invention is described below by taking a television receiver as an example.

### Embodiment 1

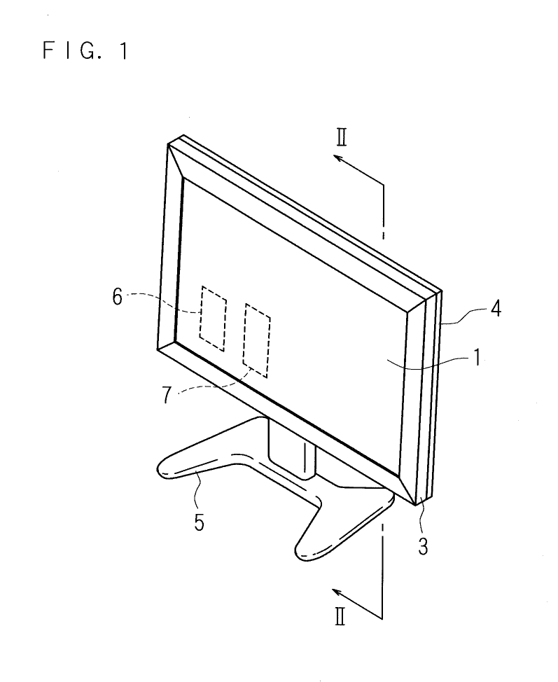

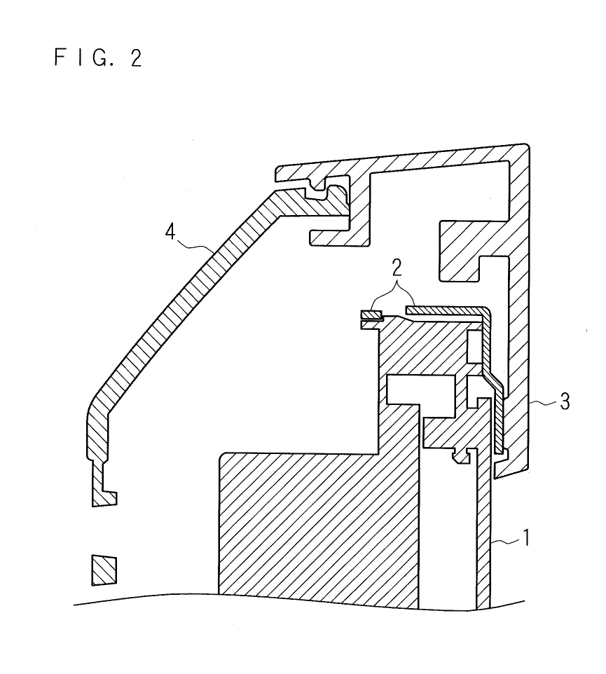

FIG. 1 is an appearance perspective view illustrating a configuration example of a television receiver according to Embodiment 1. FIG. 2 is simplified cross sectional view illustrating a cross section taken from II-II in FIG. 1, in which a main part is enlarged. In FIG. 2, the illustration is simplified as its object is to show the positional relation of main parts. The television receiver comprises a display panel unit 1, a bezel 2, a front cabinet 3, a rear cabinet 4, a stand 5, a tuner part 6 (receiving part), and a signal processing part 7.

The display panel unit 1 is configured to comprise a rectangular plate-shaped liquid crystal panel, control a voltage applied to the liquid crystal for adjusting a light transmittance, and display an image on the front of the display panel unit 1.

The bezel 2 has a rectangular frame-like shape and is positioned so as to cover a circumferential part of the display panel unit 1. The bezel 2 supports an upper side, a lower side and a front of the display panel unit 1 and stabilizes the display panel unit 1.

The front cabinet 3 has a rectangular frame-shape and is positioned so as to cover a circumferential part of the bezel 2. The front cabinet 3 stabilizes the display panel unit 1 via the bezel 2.

The rear cabinet 4 has a box-like shape on which one face is opened. The rear cabinet 4 is fixed to the front cabinet 3 so as to cover a rear face of the display panel unit 1.

The stand 5 is used for mounting the television receiver on a table or the like. The tuner part 6 receives a television broadcast and extracts a broadcast signal. The signal processing part 7 extracts image information and sound information from the broadcast signal and, based on the extracted image information, causes a display panel of the display panel unit 1 to display an image. The signal processing part 7 causes a speaker (not illustrated) to output the extracted sound information.

Next, the front cabinet 3 is described in detail. The front cabinet 3 comprises four frame members constituting respective sides of the front cabinet 3. End parts of the members constituting the sides are brought into contact with each other and coupled with a coupling metal fitting. Here, two frame members out of the four frame members are described. The remaining two frame members are not described as the structure thereof is the same as the structure of the frame members as described below.

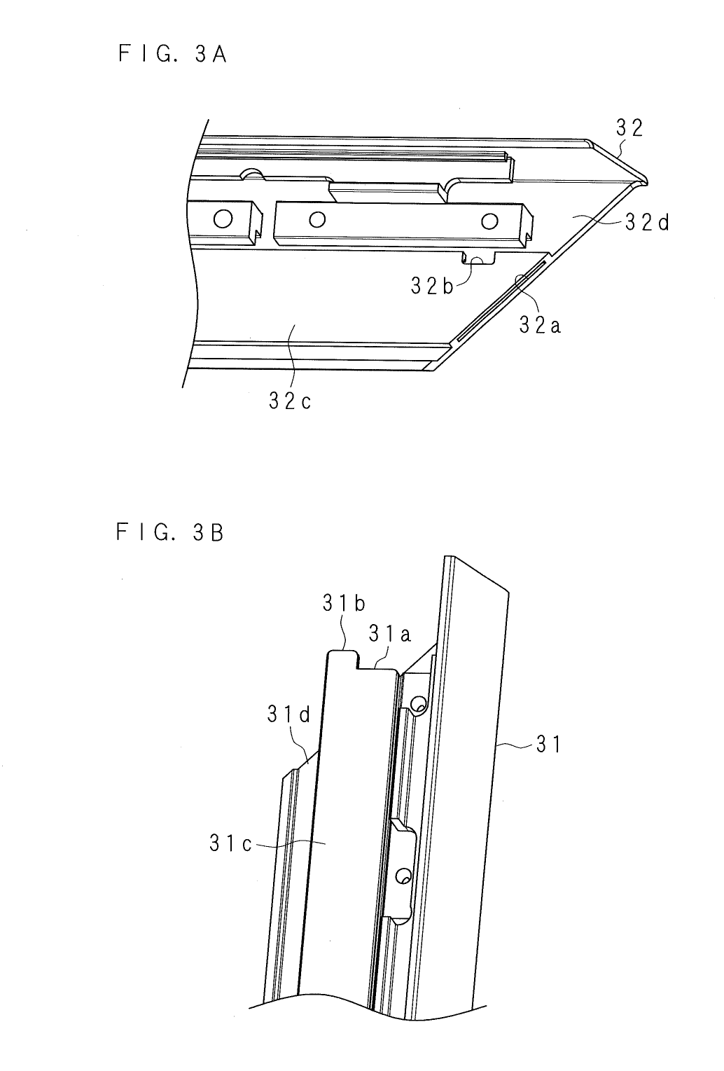

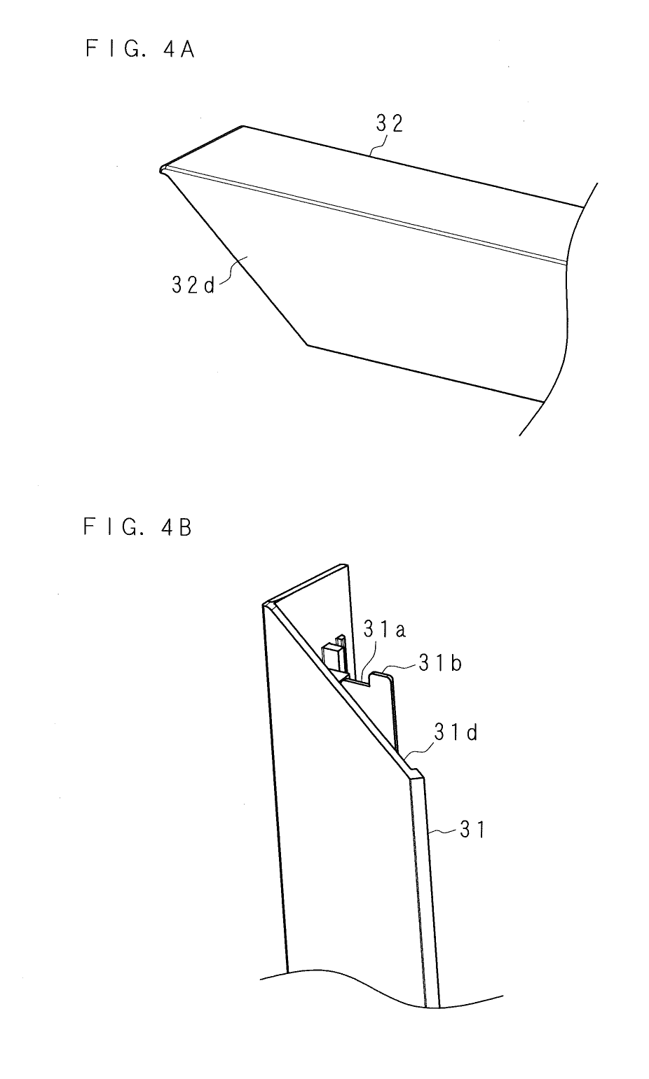

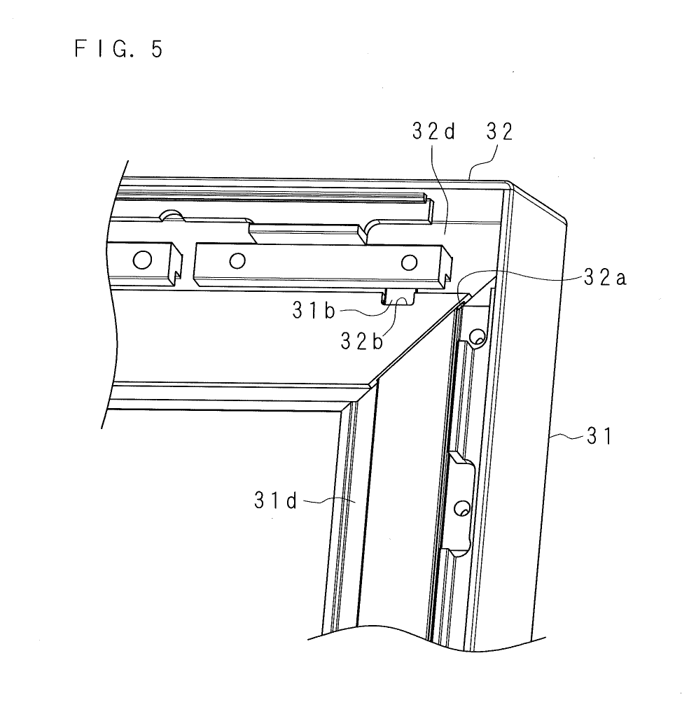

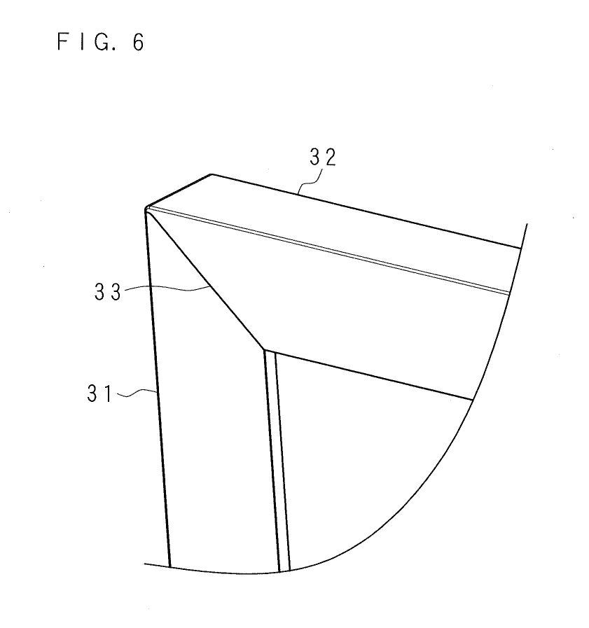

FIG. 3A, FIG. 3B, FIG. 4A and FIG. 4B are perspective views illustrating an example of the shapes of the end parts of frame members 31, 32 constituting the front cabinet 3. FIG. 5 and FIG. 6 are perspective views illustrating a coupled state of the two frame members 31, 32.

As illustrated in FIG. 3A, the frame member 32 comprises openings 32a, 32b. As illustrated in FIG. 3B and FIG. 4B, the frame member 31 comprises projections 31a, 31b.

The frame members 31, 32 are, for example, rod-shaped members which are formed by extrusion processing of aluminum and have substantially L-shaped cross sections. At a wide plate-like part 31d of the frame member 31, a thickened part 31c having a width which is about a half of the whole width of the plate-like part 31d is provided.

At an end part of the frame member 31, the wide plate-like part 31d is diagonally cut at a predetermined angle (approximately 45 degrees). The remaining thickened part 31c forms projections 31a, 31b protruding in a longitudinal direction of the frame member. As to the projecting lengths of the projections 31a, 31b, the projection 31b is longer than the projection 31a.

Similarly, an end part of the frame member 32 is cut at a similar angle as in the frame member 31.

At a thickened part 32c, an opening 32a extending from the end part in a longitudinal direction is formed. The opening 32a has a substantially rectangular cross section which is similar to the shape of the cross section of the thickened part 32c. Also, an opening 32b is formed by cutting out a wall of a side face of the thickened part 32c. The opening 32b is formed with a predetermined distance from the end part of the frame member 32. The opening 32b communicates with the opening 32a inside the thickened part 32c.

The dimensions of the openings 32a, 32b in the thickness direction are substantially the same as the thickness dimensions of the projections 31a, 31b.

Coupling of the frame member 31 and the frame member 32 is performed in the following manner. The projection 31a of the frame member 31 is fitted with the opening 32a of the frame member 32. The projection 31b is fitted with the opening 32b. FIG. 5 and FIG. 6 illustrate that the frame member 31 and the frame member 32 in a coupled state. FIG. 5 illustrates the coupled state viewed from the inside of the television receiver. FIG. 6 illustrates the coupled state viewed from the outside of the television receiver. The frame member 31 and the frame member 32 are mutually fixed by fastening a coupling metal fitting with a screw.

As the projection 31a and the opening 32a are fitted with each other, and the end face of the projection 31a comes into contact with the wall of the side face of the thickened part 32c, the movement of the frame member 31 in a longitudinal direction is regulated.

As the projection 31b and the opening 32b are fitted with each other, and a side face of the projection 31b comes into contact with a side wall (a face having a right angle to a longitudinal direction of the frame member 32) of the opening 32b, the movement of the frame member 32 in a longitudinal direction is regulated.

As described above, the frame member 31 and the frame member 32 regulate their movements mutually in a longitudinal direction.

Also, as the projection 31a and the opening 32a are fitted with each other, the wide face of the projection 31a and the wide face of the thickened part 32c which is a wall face of the opening 32a come in contact with each other. Therefore, the frame member 31 and the frame member 32 regulate their movements mutually so as not to move in the normal line direction of the wide face of the thickened part 32c. Thereby, it is possible to reduce a displacement in the coupling part 33 between the frame member 31 and the frame member 32.

Moreover, by fitting the projection 31b and the opening 32b with each other, a side face of the projection 31b and a side wall of the opening 32b come in contact with each other. Also, a tip of the projection 31a and a narrower wall (a face which is parallel to a longitudinal direction of the frame member 32) of the opening 32a come in contact with each other. Thereby, the frame member 31 and the frame member 32 mutually regulate in such a manner that they do not rotate within a flat surface which is parallel to the plate-like part 31d and the plate-like part 32d. Accordingly, it is possible to reduce a gap of the coupling part 33 between the frame member 31 and the frame member 32.

In the above description, an example in which one end of the frame member 31 and one end of the frame member 32 are coupled is shown. Here, another pair of frame members which are similar to the frame member 31 and the frame member 32 is prepared. It is possible to form a rectangular-shaped front cabinet 3 by coupling the above-mentioned frame members with each other or coupling the above-mentioned members with the other end of the frame member 31 or the other end of the frame member 32 in the above-mentioned manner.

In the above-mentioned description, only one pair of the projection 31b and the opening 32b is described. However, it is not restricted to this case but a plurality of pairs can be provided. Also, a projection and an opening may be provided at both the frame member 31 and the frame member 32.

### Embodiment 2

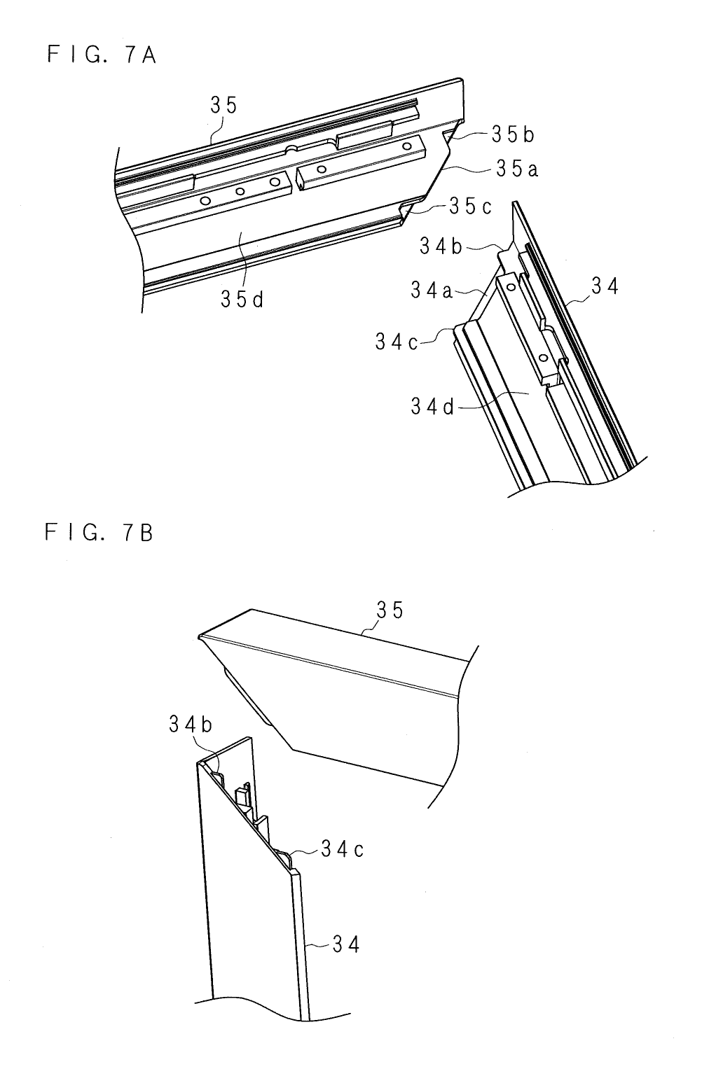

FIG. 7A and FIG. 7B are perspective views illustrating an example of shapes of end parts of frame members 34, 35 constituting a front cabinet 3 according to Embodiment 2. FIG. 7A illustrates the end part viewed from the inside of a television receiver. FIG. 7B illustrates the end part viewed from the outside of the television receiver.

As illustrated in FIGS. 7A and 7B, the frame member 34 comprises a recessed part 34a and projected parts 34b, 34c. As illustrated in FIG. 7A, the frame member 35 comprises a projected part 35a and recessed parts 35b, 35c.

The frame member 34 is, for example, a rod-shaped member which is formed by extrusion processing of aluminum and has an L-shaped cross section. At the end part of the frame member 34, a plate-like part 34d having a wider width is diagonally cut by about a half of the thickness of the plate-like part 34d at a predetermined angle (approximately 45 degrees). The remaining thickened part forms the projected parts 34b, 34c. Each of the projected parts 34b, 34c is formed into a substantially triangular shape. The projected part 34b is formed by a side parallel to a longitudinal direction, a side which connects to the above-mentioned side and forms a right angle with the above-mentioned side, and a side which is parallel to a cutting line of the plate-like part 34d and joints the above-mentioned two sides. The projected part 34c is formed in a similar manner. Between the projected parts 34b and 34c, a recessed part 34a having a depth which is about a half of the thickness of the plate-like part 34d is formed. The recessed part 34a has a substantially trapezoidal shape. Among the two sides parallel to each other of the recessed part 34a, one side is a cutting line of the plate-like part and the other side is parallel to the above-mentioned side. One of the remaining two sides is parallel to a longitudinal direction and connects to one side of the projected part 34b. The other side has a right angle to a longitudinal direction and connects to one side of the projected part 34c.

Similarly, the frame member 35 is formed by extrusion processing. At an end part of the frame member 35, a wide plate-like part 35d is diagonally cut by about a half of the thickness of the plate-like part 35d at a predetermined angle (approximately 45 degrees). The remaining thickened part forms the projected part 35a. The projected part 35a has a substantially trapezoidal shape. At the both sides of the projected part 35a, recessed parts 35b, 35c, each having a depth which is about a half of the thickness of the plate-like part 35d, are formed. Each of the recessed parts 35b, 35c is formed into a substantially triangular shape.

The projected parts 35a, recessed parts 35b, 35c which are formed on the frame member 35 have similar shapes to the recessed part 34a, projected parts 34b, 34c formed on the frame member 34, respectively. This allows the frame member 34 and the frame member 35 to be fitted with each other when they are coupled.

In the present embodiment, one side at a tip of each of the projected part 34b, 34c has a right angle to a longitudinal direction of the frame member 34. Thus, by fitting the projected part 34b, 34c with the recessed parts 35b, 35c, respectively, it is possible to regulate the movement of the frame member 34 in the longitudinal direction. On the other hand, as one side of each of the recessed parts 35b, 35c of the frame member 35 has a right angle to a longitudinal direction, by fitting the recessed parts 35b, 35c with the projected part 34b, 34c, respectively, it is possible to regulate the movement of the frame member 35 in the longitudinal direction.

As discussed above, the frame members 34, 35 regulate their movements mutually in a longitudinal direction.

Also, the projected parts and the recessed parts are formed alternately with each other along the end parts of the frame member 34 and the frame member 35. With this arrangement, the frame member 34 and the frame member 35 mutually regulate their movements in a normal line direction of a face which is parallel to the plate-like parts 34d and 35d. Therefore, it is possible to reduce a displacement in the coupling part between the frame member 34 and the frame member 35.

In the present embodiment, as in Embodiment 1, it is possible to constitute a front cabinet 3 having a rectangular shape by preparing another pair of frame members similar to the frame member 34 and the frame member 35, and coupling the above-mentioned members in a similar manner.

### Embodiment 3

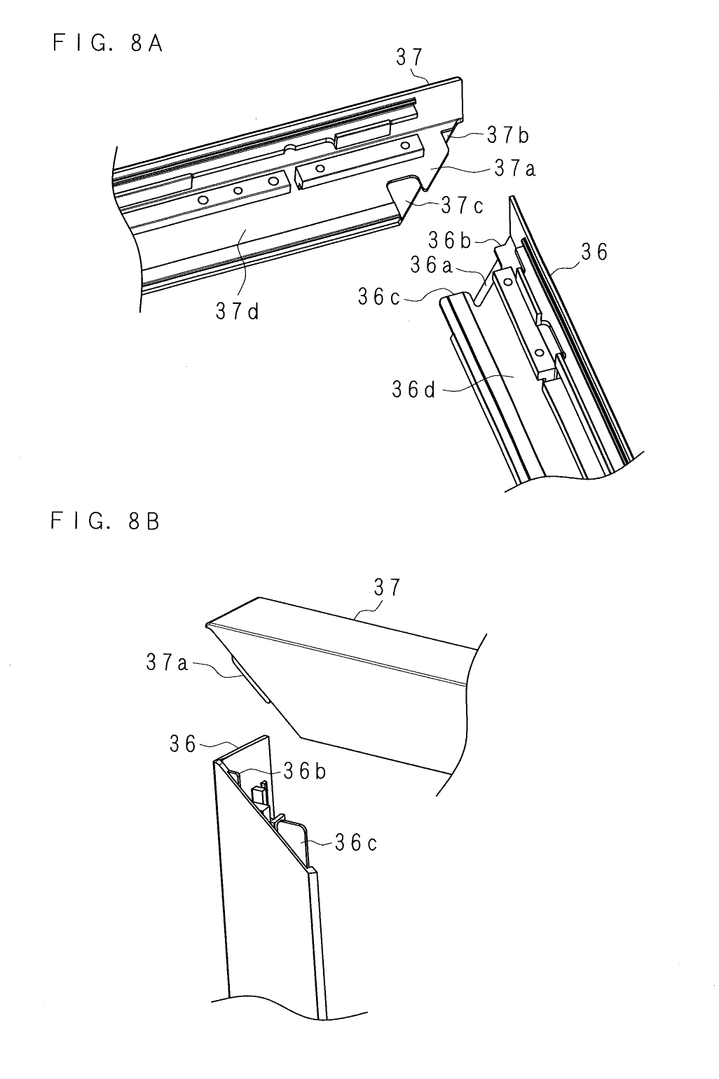

FIG. 8A and FIG. 8B are perspective views illustrating an example of shapes of end parts of frame members constituting a front cabinet 3 according to Embodiment 3. FIG. 8A illustrates the end parts viewed from the inside of a television receiver. FIG. 8B illustrates the end parts viewed from the outside of the television receiver.

As illustrated in FIGS. 8A, 8B, a frame member 36 comprises a recessed part 36a, projected parts 36b and 36c. As illustrated in FIG. 8A, a frame member 37 comprises a projected part 37a, recessed parts 37b and 37c.

The frame members 36, 37 in the present embodiment and the above-mentioned frame members 34, 35 are different in the shapes of projected parts and recessed parts and are similar in the other parts. Accordingly, the different points are mainly described.

The recessed part 36a of the frame member 36 and the projected part 37a of the frame member 37 are each formed into a substantially parallelogrammic shape. The projected part 36b of the frame member 36 and the recessed part 37b of the frame member 37 are each formed into a substantially triangular shape. The projected part 36c of the frame member 36 and the recessed part 37c of the frame member 37 are each formed into a substantially trapezoidal shape.

The projected part 36a of the frame member 36 is formed with two sides which are parallel to a longitudinal direction, and two sides which are parallel to a cutting line of a plate-like part 36d. One of the two sides which are parallel to a longitudinal direction is substantially the same as one side of the projected part 36b, and the other side is substantially the same as one side of the projected part 36c.

The projected part 36b of the frame member 36 is formed with a side parallel to a longitudinal direction, a side which connects to the above-mentioned side and forms a right angle with the above-mentioned side, and a side which is parallel to the cutting line of the plate-like part 36d and joints the above-mentioned two sides.

The projected part 36c is formed with two sides which are parallel to a longitudinal direction, a side which forms a right angle to the longitudinal direction, and a side which is parallel to the cutting line of the plate-like part 36d.

The projected parts 37a, and the recessed parts 37b, 37c which are formed on the frame member 37 have similar shapes with the recessed part 36a and the projected parts 36b, 36c which are formed on the frame member 36, respectively. This allows the frame member 36 and the frame member 37 to be fitted with each other when they are coupled.

In the present embodiment, the projected parts 36b, 36c of the frame member 36 has a side which is parallel to a longitudinal direction and a side having a right angle to a longitudinal direction.

The recessed part 36a has a side which is parallel to a longitudinal direction. The recessed parts 37b, 37c of the frame member 37 have a side which is parallel to a longitudinal direction and a side having a right angle to a longitudinal direction. The projected part 37a has a side having a right angle to the longitudinal direction.

The recessed part 36a and the projected parts 36b, 36c of the frame member 36 are fitted with the projected part 37a and the recessed parts 37b, 37c of the frame member 37, respectively. With this arrangement, the sides of the projected parts and the recessed parts, which are perpendicular to or parallel to a longitudinal direction, are brought into contact with each other, whereby the frame members 36, 37 mutually regulate their movements in a longitudinal direction.

Also, the projected parts and the recessed parts are formed alternately to correspond to one another along the end parts of the frame member 36 and the frame member 37. With this arrangement, the frame member 36 and the frame member 37 mutually regulate their movements in a right angle direction with respect to a plane including the plate-like parts 36d, 37d.

Therefore, it is possible to reduce a displacement in the coupling part between the frame member 36 and the frame member 37.

Also, the recessed part 37c has a wall face extending in a perpendicular to a longitudinal direction of the frame member 37, and the wall face is in contact with a side face of the projected part 36c of the frame member 36. Thereby, the frame member 36 and the frame member 37 mutually regulate in such a manner that they do not rotate within a plane including the plate-like parts 36d, 37d. Accordingly, it is possible to reduce a gap between the frame member 36 and the frame member 37.

In the present embodiment, as in Embodiment 1 or Embodiment 2, it is possible to constitute a rectangular-shaped front cabinet 3 by preparing another pair of members similar to the frame member 36 and the frame member 37, and coupling such another pair of members in a similar manner.

### Embodiment 4

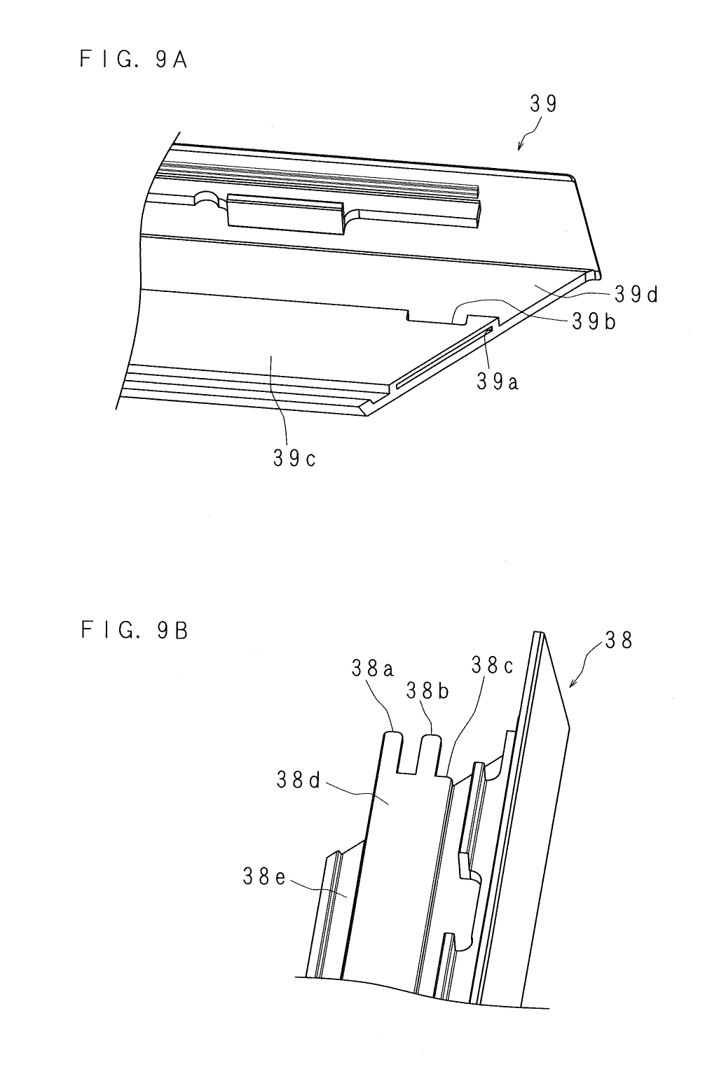

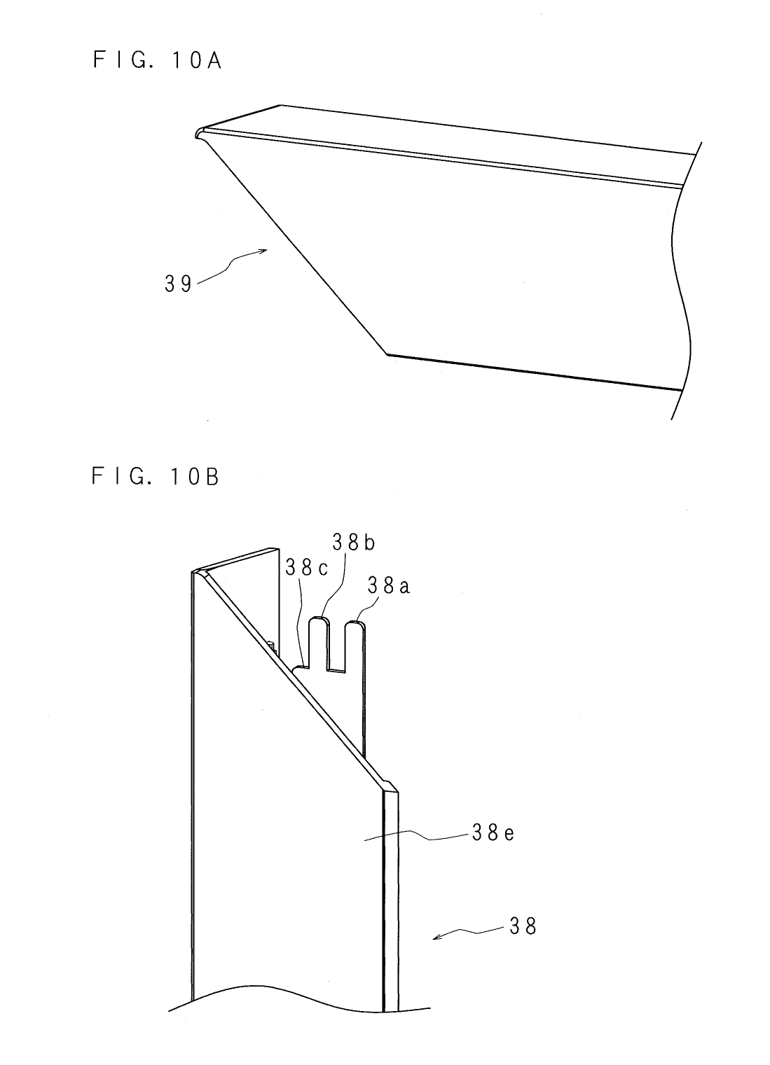

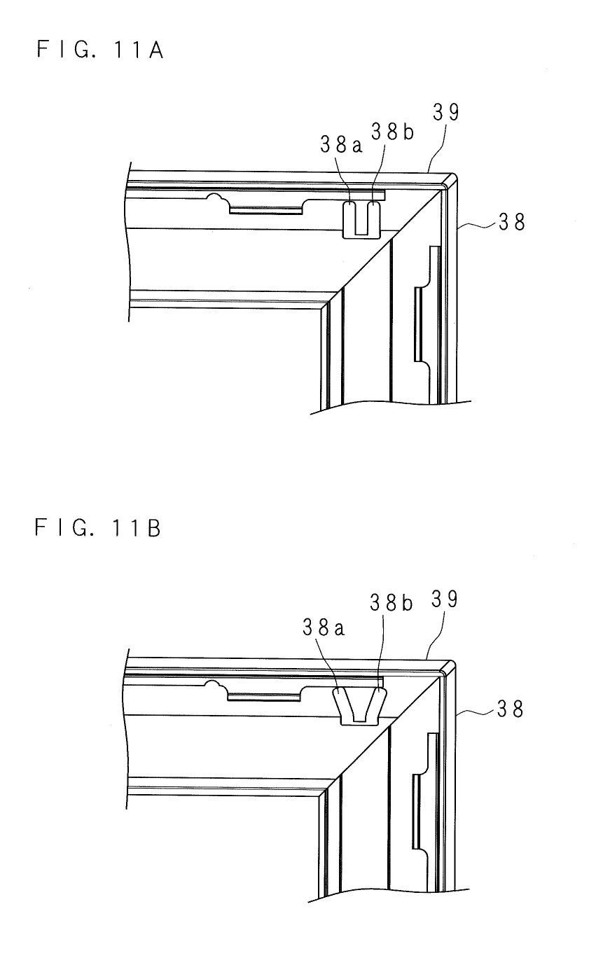

FIG. 9A, FIG. 9B, FIG. 10A and FIG. 10B are perspective views illustrating an example of a shape of an end part of a frame member constituting a front cabinet 3 according to Embodiment 4. FIG. 11A and FIG. 11B are perspective views illustrating a coupled state of two frame members 38, 39. As illustrated in FIG. 9A, the frame member 39 comprises openings 39a, 39b (hole). As illustrated in FIG. 9B and FIG. 10B, the frame member 38 comprises projections 38a, 38b (bifurcated part).

The frame members 38, 39 are, for example, rod-shaped members which are formed by extrusion processing of aluminum and have substantially L-shaped cross sections. At a wide plate-like part 38e of the frame member 38, a thickened part 38d having a width which is about a half of the whole width of the plate-like part 38e is provided.

At an end part of the frame member 38, the wide plate-like part 38e is diagonally cut at a predetermined angle (approximately 45 degrees). The remaining thickened part 38d forms projections 38a, 38b with a bifurcated shape at a tip in a longitudinal direction of the frame member 38. The projections 38a, 38b have substantially the same projecting lengths and the widths. Also, the projection 38a is formed from one of the outer edges of the thickened part 38d while the projection 38b is formed with a predetermined distance from the other outer edge of the thickened part 38d. Therefore, a projection 38c with a shorter projecting length than those of the projections 38a, 38b is formed.

An end part of the frame member 39 is cut at a similar angle as in the frame member 38. At a wide plate-like part 39d of the frame member 39, a thickened part 39c having a width which is about a half of the whole width of the plate-like part 39d is provided.

At the thickened part 39c, an opening 39a extending from the end part in a longitudinal direction is formed. The opening 39a has a substantially rectangular cross section which is similar to the shape of the cross section of the thickened part 39c. Also, an opening 39b is formed by cutting out a wall of a side face of the thickened part 39c. The opening 39b is formed with a predetermined distance from the end part of the frame member 39. The opening 39b communicates with the opening 39a inside the thickened part 39c.

The dimensions of the openings 39a, 39b in the thickness direction are substantially the same with the thickness dimensions of the projections 38a, 38b.

Coupling of the frame member 38 and the frame member 39 is performed in the following manner. The projections 38a, 38b, 38c of the frame member 38 are inserted into the opening 39a of the frame member 39. The projection 38c is brought into contact with a wall of a side face of the thickened part 39c of the frame member 39. The projections 38a, 38b are fitted with the opening 39b of the frame member 39. FIG. 11A illustrates that the frame member 38 and the frame member 39 are in a fitted state.

FIG. 11A illustrates a state in which the frame member 38 and the frame member 39 are merely fitted with each other but not fixed. In order to fix the frame members 38 and 39, the projections 38a, 38b of the frame member 38 are bent in mutually separating directions. FIG. 11B illustrates a state in which the projections 38a, 38b are bent. A tool, such as a driver, may be used for bending the projections 38a, 38b.

As the projection 38c and the opening 39a are fitted with each other, and the end face of the projection 38c and the wall of the side face of the thickened part 39c come in contact with each other, the movement of the frame member 38 in a longitudinal direction is regulated.

The projections 38a and 38b are fitted with the opening 39b. A side face of the projection 38a, which does not face a side of the projection 38b, is fitted with the opening 39b. A side face of the projection 38b, which does not face a side of the projection 38a, is fitted with the opening 39b. Also, the projections 38a, 38b are bent in mutually separating directions. Since a space between the projection 38a and the projection 38b is greater than the dimension of the opening 39b, the projections 38a, 38b are fixed to the opening 39b.

That is, the space (separating distance) between the projection 38a (one end of the bifurcated part) and the projection 38b (the other end of the bifurcated part) is a partially greater than the dimension of the opening 39b (hole). This regulates the movement of the frame member 39 in a longitudinal direction.

Also, as the projection 38c and the opening 39a are fitted with each other, a wide face of the projection 38c and a wide face of the thickened part 39c which is a wall face of the opening 39a come in contact with each other. Therefore, the frame member 38 and the frame member 39 mutually regulate their movements in a normal line direction of the wide face of the thickened part 39c. Thereby, it is possible to reduce a displacement in the coupling part between the frame member 38 and the frame member 39.

Moreover, by fitting the projection 38a, 38b and the opening 39b with each other, side faces of the projections 38a, 38b and a side wall of the opening 39b come in contact with each other. Also, a tip of the projection 38c and a narrow wall (a face which is parallel to a longitudinal direction of the frame member 39) of the opening 39a come in contact with each other. Thereby, the frame member 38 and the frame member 39 mutually regulate in such a manner that they do not rotate within a plane which is parallel to the plate-like part 38e and the plate-like part 39d. Accordingly, it is possible to reduce a gap of the coupling part between the frame member 38 and the frame member 39.

In the above-mentioned description, the regulating parts are described as a projection or a projected part and an opening or a recessed part. However, the regulating part may be formed into other shapes as long as it can regulate a relative movement of frame members by engaging with each other.

Moreover, in the description above, though aluminum is used as a material for constituting the frame members 31 and 32, 34 and 35, 36 and 37 as well as 38 and 39, it is not restricted to the case. Other metals suitable for protrusion processing, such as magnesium alloy, copper, steel, titanium, nickel or the like, may also be adopted.

It should be understood that the embodiments described above are only illustrative but not limitative. The scope of the present invention is defined in the claims and includes all changes that fall within metes and bounds of the claims or equivalence of such metes and bounds thereof, but not limited to the above description.

1-7. (canceled)

8. A display device comprising:
a display panel that displays an image; and
a rectangular flame-shaped cabinet that covers a circumferential part of the display panel, wherein
the cabinet is formed by bringing end parts of members constituting sides of a rectangular frame into contact with each other so as to couple the members with each other, the cabinet comprising:
a projection provided at one of the coupled members and protruding from a contacting end part in a longitudinal direction; and
a projection receiving part provided at another one of the coupled member and having a hole which the projection penetrates.

9. The display device according to claim 8, wherein
said another member further comprises a second projection protruding from the contacting end part in a longitudinal direction; and
said one member further comprises a second projection receiving part that engages with the second projection.

10. The display device according to claim 8, wherein
the projection comprises a bifurcated part at a tip of the projection, and
a separating distance between one end and another end of the bifurcated part, which project from the hole, is partially greater than a dimension of the hole.

11. A television receiver comprising:
the display device according to claim 8; and
a receiving part that receives a television broadcast, wherein
an image is displayed on the display device based on the television broadcast received at the receiving part.

12. A television receiver comprising:
the display device according to claim 10; and
a receiving part that receives a television broadcast, wherein
an image is displayed on the display device based on the television broadcast received at the receiving part.

13. The display device according to claim 9, wherein
the projection comprises a bifurcated part at a tip of the projection, and
a separating distance between one end and another end of the bifurcated part, which project from the hole, is partially greater than a dimension of the hole.

14. A television receiver comprising:
the display device according to claim 9; and
a receiving part that receives a television broadcast, wherein
an image is displayed on the display device based on the television broadcast received at the receiving part.
